(19) United States
(12) Patent Application Publication
(10) Pub. No.: US 2015/0061710 A1
(43) Pub. Date: Mar. 5, 2015

(54) SEMICONDUCTOR APPARATUS AND TEST METHOD

(71) Applicant: SK hynix Inc., Icheon-si Gyeonggi-do (KR)

(72) Inventor: Dong Uk LEE, Icheon-si Gyeonggi-do (KR)

(73) Assignee: SK hynix Inc., Icheon-si Gyeonggi-do (KR)

(21) Appl. No.: 14/140,372

(22) Filed: Dec. 24, 2013

(30) Foreign Application Priority Data
Aug. 30, 2013 (KR) 10-2013-0104933

(51) Int. Cl. G01R 31/26

(52) U.S. Cl. CPC G01R 31/2644
USPC 324/750.3

(57) ABSTRACT

A test driver selection unit configured to enable a plurality of test driver selection signals in response to a test pulse and a test clock, and a plurality of drivers configured to receive the plurality of test driver selection signals, wherein each of the plurality of drivers is configured to output an output signal to a data bump in response to a test driver selection signal, data, and an output enable signal, and to receive a first driving voltage and a second driving voltage.

### CROSS-REFERENCES TO RELATED APPLICATION

The present application claims priority under 35 U.S.C. §119(a) to Korean application number 10-2013-0104933, filed on Aug. 30, 2013, in the Korean Intellectual Property Office, which is incorporated herein by reference in its entirety.

### BACKGROUND

1. Technical Field

Various embodiments relate to a semiconductor integrated circuit, and more particularly, to a semiconductor apparatus.

2. Description of Related Art

A semiconductor apparatus includes a configuration for receiving a signal from an exterior and outputting a signal to the outside.

A configuration for outputting a signal to the outside in a semiconductor apparatus is called a driver, wherein the driver must normally transmit a signal to an external device in order for the semiconductor apparatus to normally operate.

When the high-integration and miniaturization of a semiconductor apparatus, the size of a pad which electrically couples the semiconductor apparatus to an external device is decreasing. Currently, a micro-bump among small-sized pads is used the most. However, since the micro-bump is too small to bring a pin of a test device into contact with the micro-bump, it is impossible to test whether or not a signal outputted to the micro-bump through a driver is normal, so that it is difficult to check whether or not the driver is poor.

### SUMMARY

A semiconductor apparatus capable of testing whether or not a driver outputting a signal to a micro-bump is poor is described herein.

In an embodiment of the invention, a semiconductor apparatus includes: a test driver selection unit configured to enable a plurality of test driver selection signals in response to a test pulse and a test clock; and a plurality of drivers configured to receive the plurality of test driver selection signals, wherein each of the plurality of drivers is configured to output an output signal to a data bump in response to a test driver selection signal, data, and an output enable signal, and to receive a first driving voltage and a second driving voltage.

In an embodiment of the invention, a method for testing a driver, configured to comprise a pull-up unit which performs a pull-up operation on an output node when a first driving signal is enabled, and a pull-down operation on the output node when a second driving signal is enabled, includes: enabling the first and second driving signals to enable the pull-up operation and the pull-down operation to be performed; applying a first driving voltage to a first driving voltage line, and applying the voltage level of a second driving voltage to a second driving voltage line electrically; and checking the amount of current which flows from the first driving voltage line to the second driving voltage line.

In an embodiment of the invention, a semiconductor apparatus includes: a test driver selection unit configured to enable a first driver selection signal and a second driver selection signal when a test clock transitions to a specific level; and a first driver and a second driver configured to output an output signal to a first data bump and a second data bump respectively.

### BRIEF DESCRIPTION OF THE DRAWINGS

Features, aspects, and embodiments are described in conjunction with the attached drawings, in which:

FIG. 1 is a block diagram illustrating the configuration of a semiconductor apparatus according to an embodiment of the invention;

FIG. 2 is a block diagram illustrating the configuration of a test driver selection unit capable of being implemented in the configuration of FIG. 1; and

FIG. 3 is a block diagram illustrating the configuration of a first driver capable of being implemented in the configuration of FIG. 1.

FIG. 4 is a block diagram illustrating the semiconductor apparatus in relation to a microprocessor according to an embodiment of the invention.

### DETAILED DESCRIPTION

Hereinafter, a semiconductor apparatus and a test method according to the invention will be described below with reference to the accompanying drawings through various embodiments.

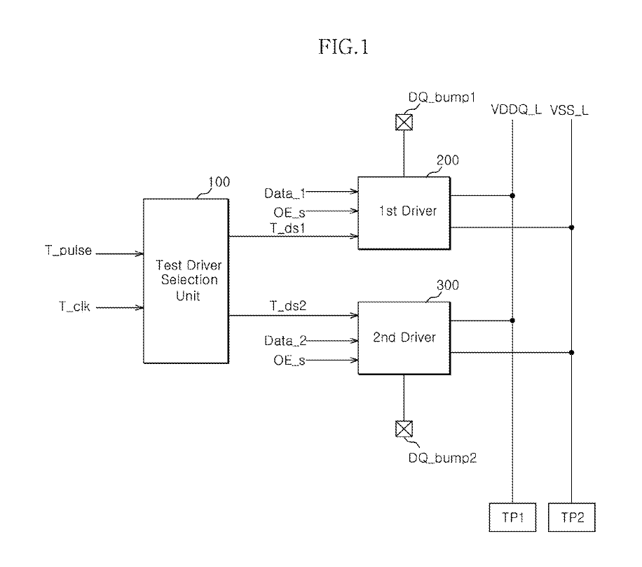

As illustrated in FIG. 1, a semiconductor apparatus according to an embodiment of the invention can include a test driver selection unit 100, a first driver 200, and a second driver 300.

The test driver selection unit 100 enables first and second test driver selection signals T_ds1 and T_ds2, respectively, in regular sequence in response to a test pulse T_pulse and a test clock T_clk. For example, the test driver selection unit 100 may enable the first and second test driver selection signals T_ds1 and T_ds2 in regular sequence whenever the test pulse T_pulse is inputted and the test clock T_clk transitions to a specific level. In addition, the test driver selection unit 100 may disable the test driver selection signal T_ds1 or T_ds2, which is enabled as the test clock T_clk transitions to the specific level, when the test clock T_clk again transitions to the specific level.

The first driver 200 outputs an output signal to a first data bump DQ_bump1 in response to first data Data_{—}1, an output enable signal OE_s, and the first test driver selection signal T_ds1. For example, the first driver 200 may output and generate an output signal in response to the first data Data_{—}1 when the first test driver selection signal T_ds1 is disabled and the output enable signal OE_s is enabled. In addition, the first driver 200 may generate an output signal having a specific voltage level, regardless of the output enable signal OE_s and the first data Data_{—}1, when the first test driver selection signal T_ds1 is enabled. That is to say, the first driver 200 may output the specific voltage to the first data bump DQ_bump1, regardless of the output enable signal OE_s and the first data Data_{—}1, when the first test driver selection signal T_ds1 inputted to the first driver 200 is enabled. The first driver 200 receives a first driving voltage VDDQ from a first driving voltage line VDDQ_L, and receives a second driving voltage VSS from a second driving voltage line VSS_L.

The second driver 300 outputs an output signal to a second data bump DQ_bump2 in response to second data Data_{—}2, the output enable signal OE_s, and the second test driver selection signal T_ds2. For example, the second driver 300 may generate and output an output signal in response to the second data Data_{—}2 when the second test driver selection signal T_ds2 is disabled and the output enable signal OE_s is enabled. In addition, the second driver 300 may generate an output signal having a specific voltage level, regardless of the output enable signal OE_s and the second data Data_{—}2, when the second test driver selection signal T_ds2 inputted to the second driver 300 is enabled. That is to say, the second driver 300 may output the specific voltage to the second data bump DQ_bump2, regardless of the output enable signal OE_s and the second data Data_{—}2, when the second test driver selection signal T_ds2 is enabled. The second driver 300 receives a first driving voltage VDDQ from a first driving voltage line VDDQ_L, and receives a second driving voltage VSS from a second driving voltage line VSS_L. In this case, the first driving voltage line VDDQ_L is electrically coupled to a first test pad TP1, and the second driving voltage line VSS_L is electrically coupled to a second test pad TP2.

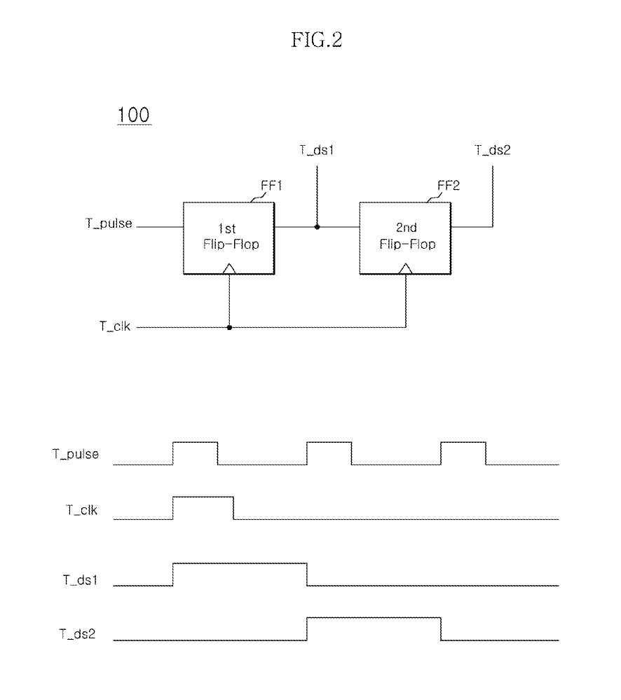

As illustrated in FIG. 2, the test driver selection unit 100 can include first and second flip-flops FF1 and FF2, respectively, which are electrically coupled to in series to each other.

The first flip-flop FF1 receives the test clock T_clk and the test pulse T_pulse, and outputs the first test driver selection signal T_ds1.

The second flip-flop FF2 receives the test clock T_clk and the first test driver selection signal T_ds1, and outputs the second test driver selection signal T_ds2.

The operation of the test driver selection unit 100 will be described as follows with reference to a timing diagram.

When the test pulse T_pulse is inputted and the test clock T_clk transitions to a high level, the first flip-flop FF1 may output the first test driver selection signal T_ds1 enabled to a high level.

When the test clock T_clk again transitions to a high level, the first flip-flop FF1 may disable the first test driver selection signal T_ds1 to a low level.

When the test clock T_clk again transitions to a high level, i.e. when the first test driver selection signal T_ds1 may be disabled to a low level, the second flip-flop FF2 may enable the second test driver selection signal T_ds2 to a high level.

When the test clock T_clk transitions to a high level after the second test driver selection signal T_ds2 has been enabled, the second flip-flop FF2 may disable the second test driver selection signal T_ds2 to a low level.

The second driver 300 is only different from the first driver 200 in input and output signals, and has the same configuration as the first driver 200. Accordingly, the test driver selection unit 100 may be configured to enable the first driver selection signal T_ds1 and second driver selection signal T_ds2 in a regulation sequence when the test pulse T_pulse is inputted and the test clock T_clk transitions to a specific level.

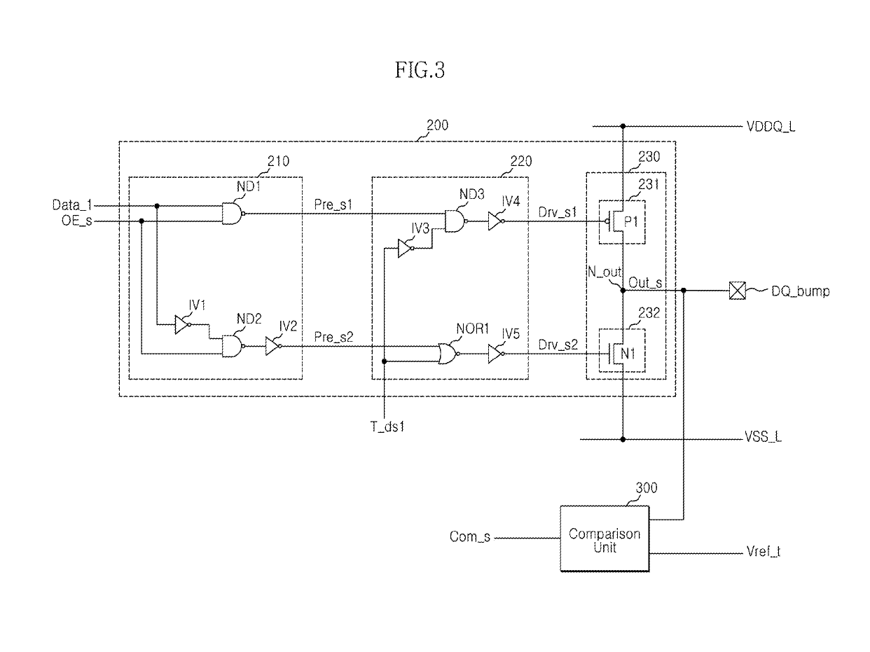

As illustrated in FIG. 3, the first driver 200 can include a pre-driver 210, a controller 220, and a main driver 230.

The pre-driver 210 generates first and second preliminary signals Pre_s1 and Pre_s2, respectively, in response to the output enable signal OE_s and the first data Data_{—}1 which are inputted to the pre-driver 210. For example, when the output enable signal OE_s is enabled to a high level, the pre-driver 210 may generate the first and second preliminary signals Pre_s1 and Pre_s2 according to the data value of the first data Data_{—}1. When the output enable signal OE_s is enabled, and the data value of the first data Data_{—}1 may be a high level, the pre-driver 210 may generate the first preliminary signal Pre_s1 having a low level and generate the second preliminary signal Pre_s2 having a low level. When the output enable signal OE_s is enabled, and the data value of the first data Data_{—}1 may be a low level, the pre-driver 210 may generate the first preliminary signal Pre_s1 having a high level and generate the second preliminary signal Pre_s2 having a high level.

The pre-driver 210 can include first and second NAND gates ND1 and ND2, respectively, and first and second inverters IV1 and IV2, respectively. The first NAND gate ND1 receives the first data Data_{—}1 and the output enable signal OE_s, and outputs the first preliminary signal Pre_s1. The first inverter IV1 receives the first data Data_{—}1. The second NAND gate ND2 receives the output enable signal OE_s and the output signal of the first inverter IV1. The second inverter IV2 receives the output signal of the second NAND gate ND2, and outputs the second preliminary signal Pre_s2.

The controller 220 generates first and second driving signals Drv_s1 and Drv_s2, respectively, in response to the first test driver selection signal T_ds1 and the first and second preliminary signals Pre_s1 and Pre_s2. For example, when the first test driver selection signal T_ds1 inputted to the controller 220 is disabled, the controller 220 may generate first and second driving signals Drv_s1 and Drv_s2 having the same level in response to the first and second preliminary signals Pre_s1 and Pre_s2. That is to say, when the first test driver selection signal T_ds1 is disabled, the controller 220 may output the first and second preliminary signals Pre_s1 and Pre_s2 as the first and second driving signals Drv_s1 and Drv_s2. When the first test driver selection signal T_ds1 inputted to the controller 220 is enabled, the controller 220 may generate the first and second driving signals Drv_s1 and Drv_s2 having mutually different levels, regardless of the first and second preliminary signals Pre_s1 and Pre_s2. That is to say, when the first test driver selection signal T_ds1 is enabled, the controller 220 may enable the first driving signal Drv_s1 to a low level, regardless of the first preliminary signal Pre_s1. In addition, when the first test driver selection signal T_ds1 is enabled, the controller 220 may enable the second driving signal Drv_s2 to a high level, regardless of the second preliminary signal Pre_s2.

The controller 220 can include third to fifth inverters IV3, IV4, and IV5, respectively, a third NAND gate ND3, and a NOR gate NOR1. The third inverter IV3 receives the first test driver selection signal T_ds1. The third NAND gate ND3 receives the first preliminary signal Pre_s1 and the output signal of the third inverter IV3. The fourth inverter IV4 receives the output signal of the third NAND gate ND3, and outputs the first driving signal Drv_s1. The NOR gate NOR1 receives the second preliminary signal Pre_s2 and the first test driver selection signal T_ds1. The fifth inverter IV5 receives the output signal of the NOR gate NOR1, and outputs the second driving signal Drv_s2.

The main driver 230 performs a pull-up operation in response to the first driving signal Drv_s1, and performs a pull-down operation in response to the second driving signal Drv_s2, thereby generating the output signal.

The main driver 230 can include a pull-up unit 231 and a pull-down unit 232. A DQ_bump is also illustrated in FIG. 3.

The pull-up unit 231 performs the pull-up operation on an output node N_out, through which the output signal Out_s is outputted, in response to the first driving signal Drv_s1. For example, the pull-up unit 231 performs the pull-up operation when the first driving signal Drv_s1 is enabled to a low level. The pull-up unit 231 receives the first driving voltage VDDQ from the first driving voltage line VDDQ_L.

The pull-up unit 231 can include a first transistor P1. The first transistor P1 has a gate which receives the first driving signal Drv_s1, a source which is electrically coupled to the first driving voltage line VDDQ_L, and a drain which is electrically coupled to the output node N_out.

The pull-down unit 232 performs the pull-down operation on the output node N_out in response to the second driving signal Drv_s2. For example, the pull-down unit 232 performs the pull-down operation when the second driving signal Drv_s2 is enabled to a high level. The pull-down unit 232 receives the second driving voltage VSS from the second driving voltage line VSS_L.

The pull-down unit 232 can include a second transistor N1. The second transistor N1 has a gate which receives the second driving signal Drv_s2, a drain which is electrically coupled to the output node N_out, and a source which is electrically coupled to the second driving voltage line VSS_L.

When the output enable signal OE_s is enabled, and the first test driver selection signal T_ds1 may be disabled, the first driver 200 may drive one of the pull-up unit 231 and pull-down unit 232 according to the data value of the first data Data_{—}1. When the output enable signal OE_s and the first test driver selection signal T_ds1 are all disabled, the first driver 200 may drive neither the pull-up unit 231 nor the pull-down unit 232, regardless of the first data Data_{—}1. When the first test driver selection signal T_ds1 is enabled, the first driver 200 may drive both the pull-up unit 231 and the pull-down unit 232, regardless of the output enable signal OE_s and the first data Data_{—}1. The second driver 300 also drives a pull-up unit (not shown) and a pull-down unit (not shown) of the second driver 300, in the same manner as that in the first driver 200, in response the output enable signal OE_s, the second data Data_{—}2, and the second test driver selection signal T_ds2.

In order to measure the voltage level of the output node N_out, a comparison unit 300 for comparing the voltage level of the output node N_out with the voltage level of a reference voltage Vref_t and generating a comparison signal Com_s can be additionally included.

The operation of a semiconductor apparatus having the aforementioned configuration according to an embodiment of the invention is as follows.

A test pulse T_pulse and a test clock T_clk are inputted to the test driver selection unit 100.

When the test clock T_clk transitions to a first high level, the first test driver selection signal T_ds1 may be enabled to a high level.

When the first test driver selection signal T_ds1 is enabled to a high level, the first driver 200 may perform a pull-up operation and a pull-down operation at the same time.

Referring to FIG. 3, when the first test driver selection signal T_ds1 is enabled to a high level, the first driving signal Drv_s1 may be enabled to a low level and the second driving signal Drv_s2 may be enabled to a high level. When the first test driver selection signal T_ds1 is enabled, the controller 220 may generate and enable both the first and second driving signals Drv_s1 and Drv_s2 so that the first driver 200 can perform a pull-up operation and a pull-down operation at the same time.

The first transistor P1 of the pull-up unit 231 is turned on by the first driving signal Drv_s1 to perform a pull-up operation on the output node N_out.

The second transistor N1 of the pull-down unit 232 is turned on by the second driving signal Drv_s2 to perform a pull-down operation on the output node N_out.

The pull-up unit 231 receives the first driving voltage VDDQ from the first driving voltage line VDDQ_L to perform a pull-up operation on the output node N_out through which the output signal Out_s, in response to the first driving signal Drv_s1, and the pull-down unit 232 receives the second driving voltage VSS from the second driving voltage line VSS_L to perform a pull-down operation on the output node N_out.

When a pull-up operation is performed, the first driving voltage line VDDQ_L may be electrically coupled to the output node N_out through the first transistor P1 of the pull-up unit 231.

When a pull-down operation is performed, the second driving voltage line VSS_L may be electrically coupled to the output node N_out through the second transistor N2 of the pull-down unit 232.

The amount of current flowing from the first driving voltage line VDDQ_L to the second driving voltage line VSS_L through the first driver 200 can be checked using the first and second test pads TP1 and TP2 electrically coupled to the first and second driving voltage lines VDDQ_L and VSS_L.

When the voltage levels of the first and second driving voltages VDDQ and VSS applied to the first driver 200 are identified, and the amount of current flowing from the first driving voltage line VDDQ_L to the second driving voltage line VSS_L through the first driver 200 is measured, the resistance of the first driver 200 may be calculated by the Ohm's law (E=I×R, wherein I is current, R is resistance, and E is voltage), and thus the driving force, i.e. the size, of the first driver 200 can be identified. A resistance value of the first driver 200 may be determined with the amount of current I and voltage level difference between the first driving voltage VDDQ and the second driving voltage VSS.

By comparing the driving force of the first driver 200 with the driving force targeted on the design, it is possible to identify whether or not the first driver 200 is poor.

When the test clock T_clk transitions to a second high level, the first test driver selection signal T_ds1 may be disabled, and the second test driver selection signal T_ds2 may be enabled.

When the second test driver selection signal T_ds2 is enabled, the second driver 300 may perform a pull-up operation and a pull-down operation at the same time. In this case, the first driver 200 performs neither a pull-up operation nor a pull-down operation due to the disabled output enable signal OE_s and the disabled first test driver selection signal T_ds1.

When the second driver 300 performs the pull-up operation and the pull-down operation at the same time, the driving forth of the second driver 300 can be measured in the same manner as that used to measure the driving forth of the first driver 200, so that it can be identified whether or not the second driver 300 is poor.

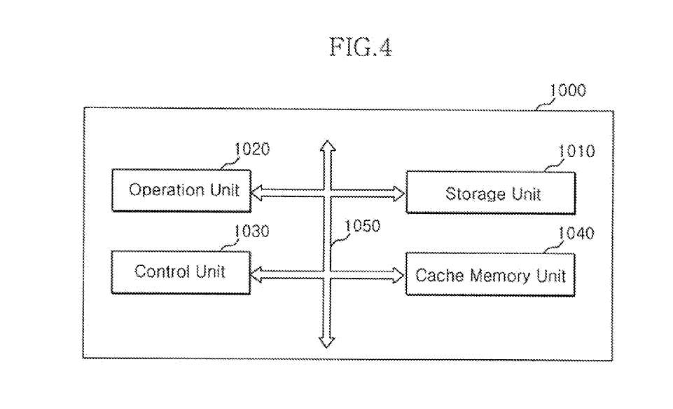

FIG. 4 illustrates a microprocessor 1000 to which the semiconductor apparatus according to an embodiment may control and adjust a series of processes, which receive data from various external apparatuses. The microprocessor 1000 may include a storage unit 1010, an operation unit 1020, and a control unit 1030. The microprocessor 1000 may be a variety of processing apparatuses, such as a central processing unit (CPU), a graphic processing unit (GPU), a digital signal processor (DSP), or an application processor (AP).

The storage unit 1010 may be a processor register and may be a unit that may store data in the microprocessor 1000 and include a data register and other various registers. The storage unit 1010 may temporarily storage data to be operated in the operation unit 1020, resulting data performed in the operation unit 1020, and an address in which the data to be operated is stored.

The storage unit 1010 may include the semiconductor apparatus. The operation unit 1020 may perform an operation in the microprocessor 1000, and perform a variety of four fundamental rules of an arithmetic operation or a logic operation depending on a decryption result of a command in the control unit 1030. The operation unit 1020 may include one or more arithmetic and logic units (ALU).

The control unit may receive a signal from the storage unit 1010, the operation unit 1020, or an external apparatus of the microprocessor 1000, perform an extraction or decryption of a command, or input or output control, and execute a process in a program form.

The microprocessor 1000 according to an embodiment may further include a cache memory unit 1040 suitable for temporarily storing data input from an external apparatus other than the storage unit 1010 or data to be output to an external apparatus. The cache memory unit 1040 may exchange data from the storage unit 1010, the operation unit 1020, and the control unit 1030 through a bus interface 1050.

A semiconductor apparatus according to the invention makes it possible to test whether or not a driver outputting a signal to a micro-bump is poor, thereby increasing the reliability of the semiconductor apparatus.

While certain embodiments have been described above, it will be understood to those skilled in the art that the embodiments described are by way of example only. Accordingly, the apparatus and method described herein should not be limited based on the described embodiments. Rather, the apparatus and method described herein should only be limited in light of the claims that follow when taken in conjunction with the above description and accompanying drawings.

What is claimed is:

1. A semiconductor apparatus comprising:
a test driver selection unit configured to enable a plurality of test driver selection signals in response to a test pulse and a test clock; and
a plurality of drivers configured to receive the plurality of test driver selection signals,
wherein each of the plurality of drivers is configured to output an output signal to a data bump in response to a test driver selection signal, data, and an output enable signal, and to receive a first driving voltage and a second driving voltage.

2. The semiconductor apparatus according to claim 1, wherein the test driver selection unit is configured to enable the plurality of test driver selection signals in a regular sequence whenever the test pulse is inputted and the test clock transitions to a specific level.

3. The semiconductor apparatus according to claim 2, wherein the test driver selection unit is configured to disable the test driver selection signal, which is enabled when the test clock transitions to the specific level, when the test clock again transitions to the specific level.

4. The semiconductor apparatus according to claim 3, wherein the test driver selection unit comprises a plurality of flip-flops which are electrically coupled in series.

5. The semiconductor apparatus according to claim 1, wherein each of the plurality of drivers is configured to generate the output signal in response to the data when the test driver selection signal inputted to the corresponding driver is disabled and the output enable signal is enabled.

6. The semiconductor apparatus according to claim 5, wherein each of the plurality of drivers is configured to generate the output signal having a specific voltage level when the test driver selection signal inputted to the corresponding driver is enabled.

7. The semiconductor apparatus according to claim 6, wherein each of the plurality of drivers comprises:
a pre-driver configured to generate a first preliminary signal and a second preliminary signal, in response to the data and the output enable signal;
a controller configured to generate first and second driving signals having an equal level in response to the first and second preliminary signals when the test driver selection signal inputted to the controller is disabled, and to generate first and second driving signals having mutually different levels when the test driver selection signal inputted to the controller is enabled; and
a main driver configured to perform a pull-up operation in response to the first driving signal and to perform a pull-down operation in response to the second driving signal, thereby generating the output signal.

8. The semiconductor apparatus according to claim 7, wherein the controller is configured to, when the test driver selection signal is enabled, generate the first and second driving signals so that the main driver performs the pull-up operation and the pull-down operation at a same time.

9. The semiconductor apparatus according to claim 8, wherein the main driver comprises:
a pull-up unit configured to perform the pull-up operation on an output node, through which the output signal is outputted, in response to the first driving signal; and
a pull-down unit configured to perform the pull-down operation on the output node in response to the second driving signal.

10. The semiconductor apparatus according to claim 9, wherein the pull-up unit is configured to receive the first driving voltage from a first driving voltage line; and
the pull-down unit is configured to receive the second driving voltage from a second driving voltage line.

11. The semiconductor apparatus according to claim 10, wherein the first driving voltage line is electrically coupled to a first test pad, and the second driving voltage line is electrically coupled to a second test pad.

12. The semiconductor apparatus according to claim 9, further comprising a comparison unit which is configured to compare the voltage level of the output node with the voltage level of a reference voltage, and to generate a comparison signal.

13. A method for testing a driver configured to comprise a pull-up unit which performs a pull-up operation on an output node when a first driving signal is enabled, and perform a pull-down operation on the output node when a second driving signal is enabled, the method comprising:
enabling the first and second driving signals to enable the pull-up operation and the pull-down operation to be performed;
applying a first driving voltage to a first driving voltage line, and applying the voltage level of a second driving voltage to a second driving voltage line; and
checking the amount of current which flows from the first driving voltage line to the second driving voltage line.

14. The method according to claim 13, comprising, after the checking of the amount of current, determining a resistance value of the driver with the amount of current and a voltage level difference between the first and second driving voltages.

15. A semiconductor apparatus comprising:
A test driver selection unit configured to enable a first driver selection signal and a second driver selection signal when a test clock transitions to a specific level; and
a first driver and a second driver configured to output an output signal to a first data bump and a second data bump respectively.

16. The semiconductor apparatus of claim 15, wherein the first driver is configured to output the output signal in response to a first data, an output enable signal, and the first driver selection signal and the second driver is configured to output the output signal in response to a second data, the output enable signal, and the second driver selection signal.

17. The semiconductor apparatus of claim 15, wherein the first driver is configured to generate the output signal with a specific voltage to the first data bump when a first test driver selection signal is enabled and the second driver is configured to generate the output signal with the specific voltage when a second test driver selection signal is enabled.

18. The semiconductor apparatus of claim 14, wherein the first driver and the second driver receive a first driving voltage from a first driving voltage line and a second driving voltage from a second driving voltage line.

19. The semiconductor apparatus of claim 17, further comprising:
a first flip-flop configured to receive a test clock and a test pulse and output the first test driver selection signal; and
a second flip-flop configured to receive the test clock and the test pulse and output the second test driver selection signal.

20. The semiconductor apparatus of claim 16, further comprising:
a pre-driver configured to generate a first preliminary signal and a second preliminary signal according to a data value of the first data when the output enable signal is enabled;
a controller configured to generate a first driving signal and a second driving signal in response the first preliminary signal and the second preliminary signal; and
a main driver configured to perform a pull-up operation and a pull-down operation on an output node.

21. The semiconductor apparatus of claim 20, wherein the main driver is configured to perform the pull-up operation when the first driving signal is at a low level and perform the pull-down operation when the second driving signal is at a high level.
